(19) United States
(12) Patent Application Publication
(10) Pub. No.: US 2010/0236599 A1
(43) Pub. Date: Sep. 23, 2010

(54) PHOTOVOLTAIC ARRANGEMENT

(76) Inventor: Richard Metzler, Pocking (DE)

Correspondence Address: JENKINS, WILSON, TAYLOR & HUNT, P. A., Suite 1200 UNIVERSITY TOWER, 3100 TOWER BLVD.,, DURHAM, NC, 27707, US

(21) Appl. No.: 12/499,320

(22) Filed: Jul. 8, 2009

(30) Foreign Application Priority Data
Mar. 23, 2009 (EP) 09155866.8

(51) Int. Cl. H01L 31/052

(52) U.S. Cl. 136/246

(57) ABSTRACT

The photovoltaic arrangement for producing electric current from light has a photovoltaic installation with a predetermined area, which has a plurality of photovoltaic modules and a number N of reflectors, each reflector having a area which is greater than the area of the photovoltaic installation and being arranged to reflect at least part of the light incident on the reflector onto the photovoltaic installation.

The invention relates to a photovoltaic arrangement for producing electric current from light.

A photovoltaic arrangement for producing electric current from light comprises in particular a photovoltaic installation with a plurality of photovoltaic modules for the direct conversion of incident light into electric current. Photovoltaic installations are therefore one of the most important options for the production of renewable energy. As well as the advantage of producing electric current directly from light, in particular sunlight, photovoltaic installations have the advantage that simple, on-site installation is possible. However, only a limited number of surfaces, such as roof tops facing south without shade, are suitable for practical installation of a photovoltaic installation in central and northern Europe without additional expenses.

To increase the efficiency and performance of a photovoltaic installation, it is known to use mirrors to guide light onto the photovoltaic installation. Conventional mirrors for increasing the amount of light incident on a photovoltaic installation are known from DE 100 26 014 A1, DE 100 25 860 A1, DE 198 14 617 A1 and DE 34 151 12 A1.

However, these conventional mirrors in the above-mentioned documents all have the common property that these proposed mirrors are of a relatively complex construction and are thus expensive to produce.

It is further particularly worth noting that in photovoltaic installations, additional mirrors or reflectors can only be put to practical use if they are considerably cheaper than the photovoltaic modules of the photovoltaic installation. Otherwise, it would be simpler and more cost-effective to increase the number of photovoltaic modules used.

It is accordingly an object of the present invention to increase the efficiency of a photovoltaic installation in a cost-effective manner.

According to the invention, this proposed object is achieved by a photovoltaic arrangement for producing electric current from light with the features of claim 1 and/or by a photovoltaic arrangement for producing electric current from light with the features of claim 8 and/or by a photovoltaic arrangement for producing electric current from light with the features of claim 15.

Accordingly, a photovoltaic arrangement for producing electric current from light is proposed, comprising:
a photovoltaic installation with a predetermined area, which has a plurality of photovoltaic modules; and
a number N of reflectors, each reflector having an area which is greater than the area of the photovoltaic installation and being adapted to reflect at least part of any light incident on the reflector onto the photovoltaic installation.

Further, a photovoltaic arrangement for producing electric current from light is proposed, comprising:
a photovoltaic installation with a plurality of photovoltaic modules;
a number N of reflectors, which are adapted to reflect at least part of the light incident on the number N of reflectors onto a number M of guide mirrors; and
the number M of guide mirrors, which are arranged in such a way as to guide the light reflected from the number N of reflectors onto the photovoltaic installation.

Furthermore, a photovoltaic arrangement for producing electric current from light is proposed, comprising:
a photovoltaic installation with a plurality of photovoltaic modules, and
a number M of guide mirrors, which are arranged in such a way as to guide light onto the photovoltaic installation, each guide mirror comprising a plurality of lamellae, arranged parallel to one another, with reflective surfaces, which lamellae are rotatably mounted in a frame, the rotatably mounted lamellae being arranged to form a predetermined mirror shape, in particular a concave mirror.

An advantage of the present invention is that the large-area reflectors are adapted to increase considerably the amount of light incident on the photovoltaic installation by redirection and limited concentration.

In this way, more electric current can accordingly be generated, and the efficiency of the photovoltaic installation is thus greatly increased. As a whole, the efficiency of a photovoltaic installation is improved according to the invention in a cost-effective manner by using low-cost reflectors and/or mirrors. The large-area reflectors comprise a reflective surface for reflecting the light incident on the reflectors onto the photovoltaic installation or onto the guide mirror or mirrors.

The reflectors are in particular aligned parallel or at an acute angle to the photovoltaic modules. The reflectors may also guide part of the incident light directly onto the photovoltaic modules of the photovoltaic installation at an obtuse angle. Part of the incident light may also be reflected at an acute angle.

To protect the photovoltaic installation from damage caused by an excessively high light intensity of the light incident on the photovoltaic installation, the reflectors and/or the guide mirrors are arranged and formed in such a way as to deflect only a predetermined percentage of the incident light so as to limit the intensity of the light shining onto the photovoltaic installation.

The predetermined percentage is for example between 20 and 75%, preferably between 20 and 50%, particularly preferably between 25 and 40%.

The reflectors are in particular formed as a cost-effective installation which allows automated mass production. An example of a cost-effective installation of this type is a canvas or a material with a reflective surface. In this way, the reflectors are consequently of a low weight and allow a flexible and very simple installation. Furthermore, the mounting of the reflectors can in particular be reversible, without a fixed connection to the ground, so that in general no planning/building permission is required. Because of the simple construction of the reflectors, simple mechanical setup, correction and guidance are also possible in order to set the optimum position and inclination of the reflectors. In particular, the reflectors are constructed so as to be corrosion, wind and weather-resistant.

The guide mirrors are preferably smaller, flexibly adjustable mirrors, which are arranged opposite the photovoltaic modules of the photovoltaic installation. The photovoltaic arrangement of the reflectors and/or mirrors makes it possible to compensate for shadows from trees or other objects, such as buildings, on the photovoltaic installation.

Furthermore, it becomes possible to use roof and façade surfaces for the installation of photovoltaic installations in an efficient and economic manner, which surfaces would be unsuitable without additional mirrors or reflectors. This applies in particular to façade surfaces for which the angle of the sun is generally unfavourable.

Advantageous configurations and embodiments of the invention can be taken from the sub-claims and the description with reference to the drawings.

According to a preferred embodiment, the area of each reflector is greater than the determined area of the photovoltaic installation at least by a factor F. The factor F is in particular between 1 and 6, preferably between 1 and 3.

According to a further preferred embodiment, the number N of reflectors is arranged in a trapezium arrangement around the photovoltaic installation. Because of the use of the trapezium arrangement of the reflectors, conventional guidance systems can be replaced in open-air operation. This replacement of the conventional guidance systems results in a further cost advantage.

According to a further preferred embodiment, each large-area reflector has a canvas made of a plastics material or of a material with a reflective surface.

According to a further preferred embodiment, each canvas has a large number of slits which are adapted to allow water to flow off and wind to pass through.

According to a further preferred embodiment, a respective fastening means is provided for reversibly fastening each canvas or the material to the ground or to a fixed means. The canvas made of plastics material or the material is preferably formed as a sail. The fastening means in particular comprises at least one break-off means, which is constructed so as to tear in very strong storms or winds so as to prevent damage caused by the sail. This break-off means is in particular formed by cords, wires or clips, which link the sail to the fastening means.

According to a further preferred embodiment, the fastening means has a height adjustment means for adjusting the height of the respective canvas relative to the ground.

According to a further preferred embodiment, the height adjustment means is set up to arrange the respective canvas at a predetermined angle and/or with a predetermined curvature.

According to a further preferred embodiment, the fastening means has a guide means, which is arranged so as to guide the respective canvas for the optimum incidence of light on the canvas.

According to a further preferred embodiment, at least one light sensor means is arranged on or in the photovoltaic installation. The light sensor means is set up to supply a detection signal in dependence on the light incident on the photovoltaic installation, in particular in dependence on the amount of light incident on the photovoltaic installation.

According to a further preferred embodiment, a control means is provided for controlling the guide means and/or the height adjustment means in dependence on the detection signal of the at least one light sensor means.

According to a further preferred embodiment, the fastening means has supports, in particular metal supports, for anchoring the respective canvas in the ground.

According to a further preferred embodiment, the number N of reflectors is between 2 and 16, preferably between 4 and 12, particularly preferably between 4 and 6.

According to a further preferred embodiment, the number M of guide mirrors is between 1 and 6, preferably between 1 and 3. Particularly preferably, the number M is equal to 2.

According to a further preferred embodiment, each reflector is arranged so as to reflect a first part of the incident light onto at least one of the guide mirrors and a second part of the incident light directly onto the photovoltaic installation in a focused form.

In particular, the photovoltaic installation has a defined first area (F1), the N reflectors have a defined second area (F2) and the M guide mirrors have a defined third area (F3), the second area being greater than the first area (F2>F1) and greater than the third area (F2>F3).

According to a further preferred embodiment, each guide mirror has a plurality of lamellae, arranged parallel to one another, with reflective surfaces. The lamellae are preferably mounted rotatably in a frame.

According to a further preferred embodiment, the rotatably mounted lamellae are adapted to form a predetermined mirror shape. The predetermined mirror shape is for example that of a concave mirror.

According to a further preferred embodiment, a respective fastening device is provided for reversibly fastening each guide mirror to the ground or to a fixed means, on which the frame of the respective guide mirror is rotatably mounted.

According to a further preferred embodiment, a control device is provided for controlling the alignment of the rotatably mounted lamellae and for controlling the formation of the predetermined mirror shape.

According to a further preferred embodiment, the fastening device has a height adjustment device for adjusting the height of the respective guide mirror relative to the ground.

According to a further preferred embodiment, the fastening device has a guide device for adjusting the inclination and/or the angle of rotation of the respective guide mirror. In particular, the guide device is set up to guide the respective guide mirror for the optimum incidence of light on the guide mirror.

According to a further preferred embodiment, a control device is provided for controlling the guide device and/or the height adjustment device in dependence on the detection signal.

According to a further preferred embodiment, the lamellae are produced from plastics material by an extrusion process. In particular, one side of each lamella is coated with a reflective metallised film.

In the following, the invention is explained in greater detail by way of the embodiments specified in the schematic drawings, in which:

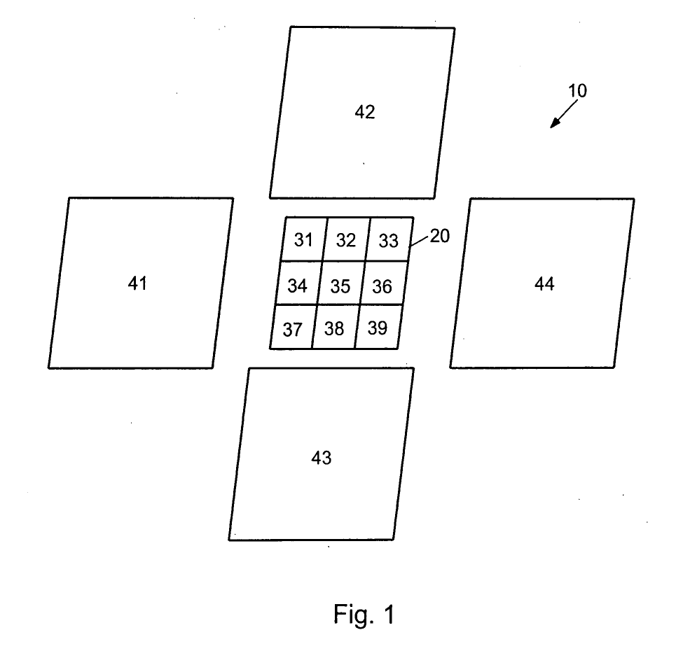

FIG. 1 is a schematic block diagram of a first embodiment of a photovoltaic arrangement according to the invention for producing electric current from light;

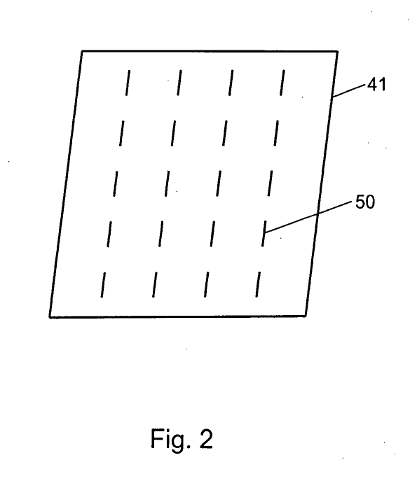

FIG. 2 is a schematic block diagram of a first embodiment of a reflector of the photovoltaic arrangement according to the invention for producing electric current from light;

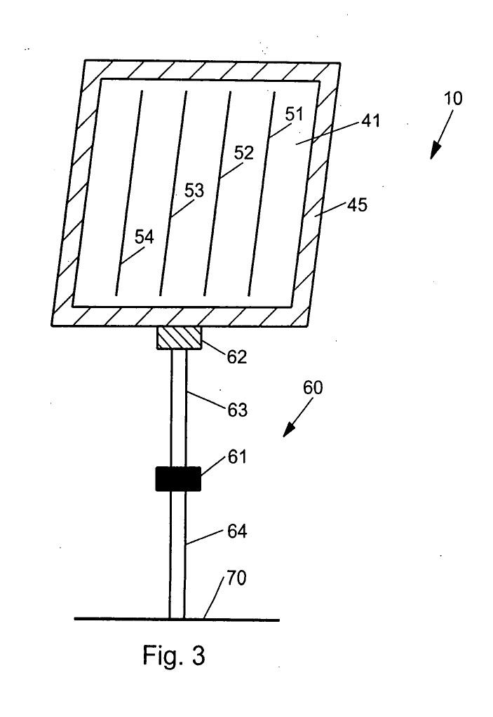

FIG. 3 is a schematic block diagram of a second embodiment of a reflector of the photovoltaic arrangement according to the invention for producing electric current from light;

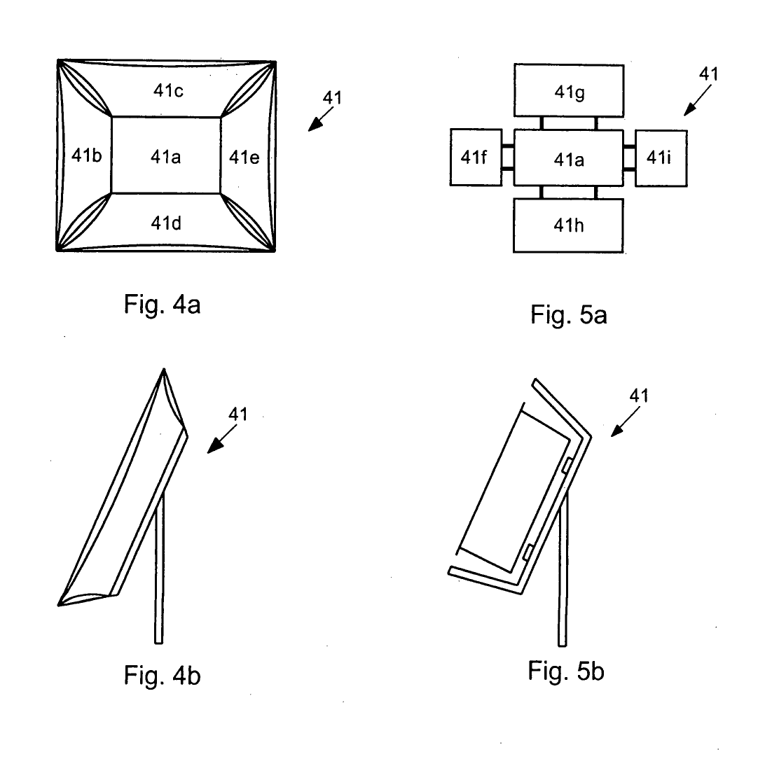

FIGS. 4a and 4b are schematic block diagrams of a third embodiment of a reflector of the photovoltaic arrangement according to the invention for producing electric current from light;

FIGS. 5a and 5b are schematic block diagrams of a fourth embodiment of a reflector of the photovoltaic arrangement according to the invention for producing electric current from light;

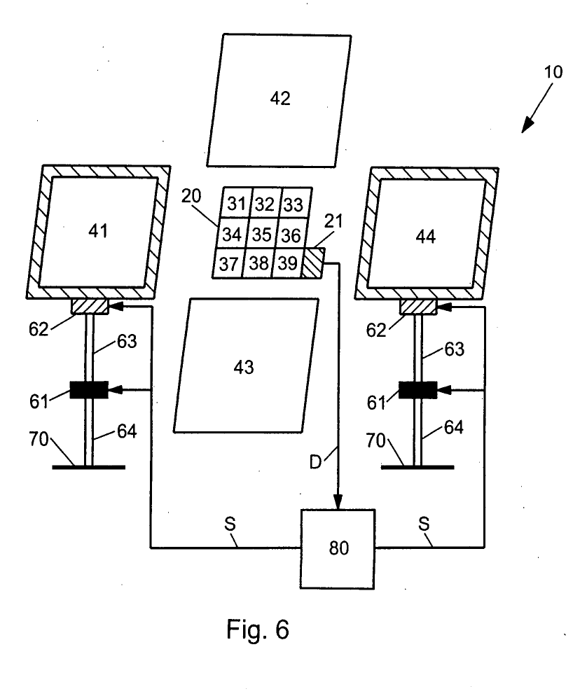

FIG. 6 is a schematic block diagram of a second embodiment of a photovoltaic arrangement according to the invention for producing electric current from light;

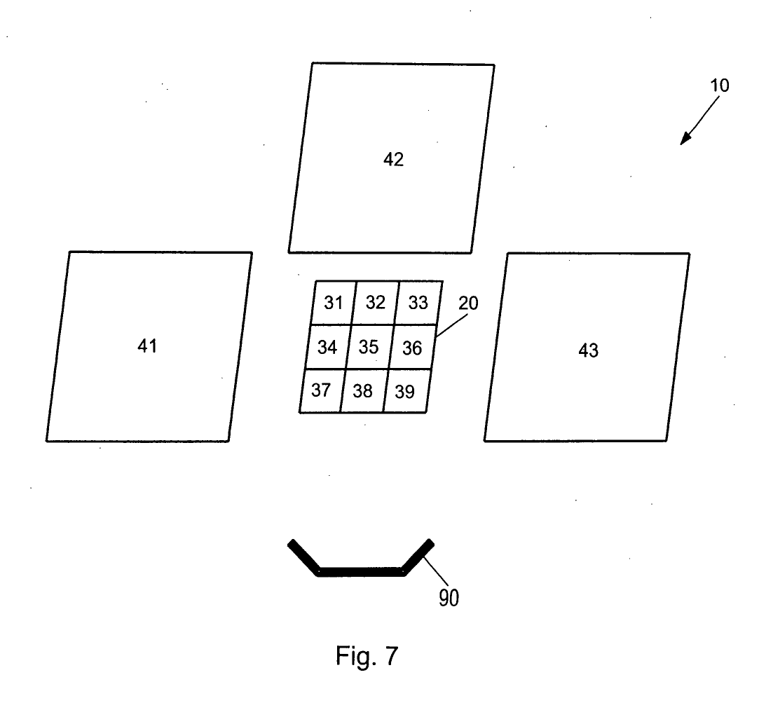

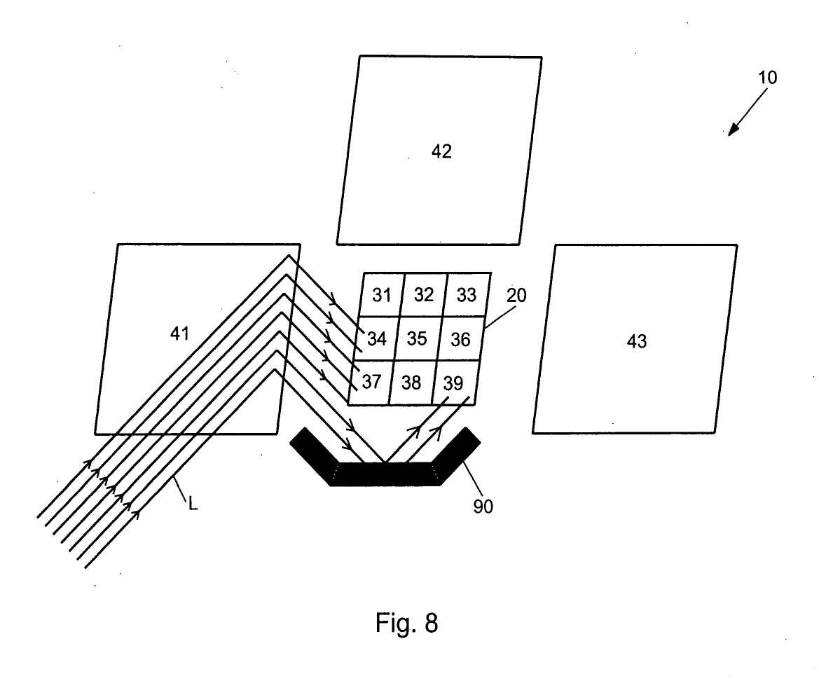

FIG. 7 is a schematic block diagram of a third embodiment of a photovoltaic arrangement according to the invention for producing electric current from light;

FIG. 8 is a schematic block diagram of the third embodiment of the photovoltaic arrangement of FIG. 7 according to the invention, including a representation of an example incidence of light;

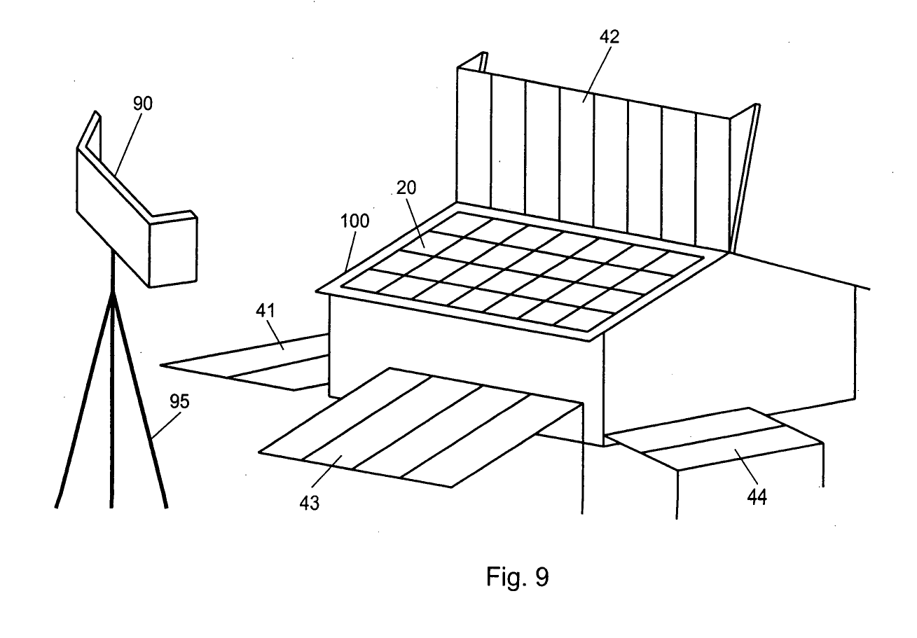

FIG. 9 is a schematic block diagram of a fourth embodiment of a photovoltaic arrangement according to the invention for producing electric current from light;

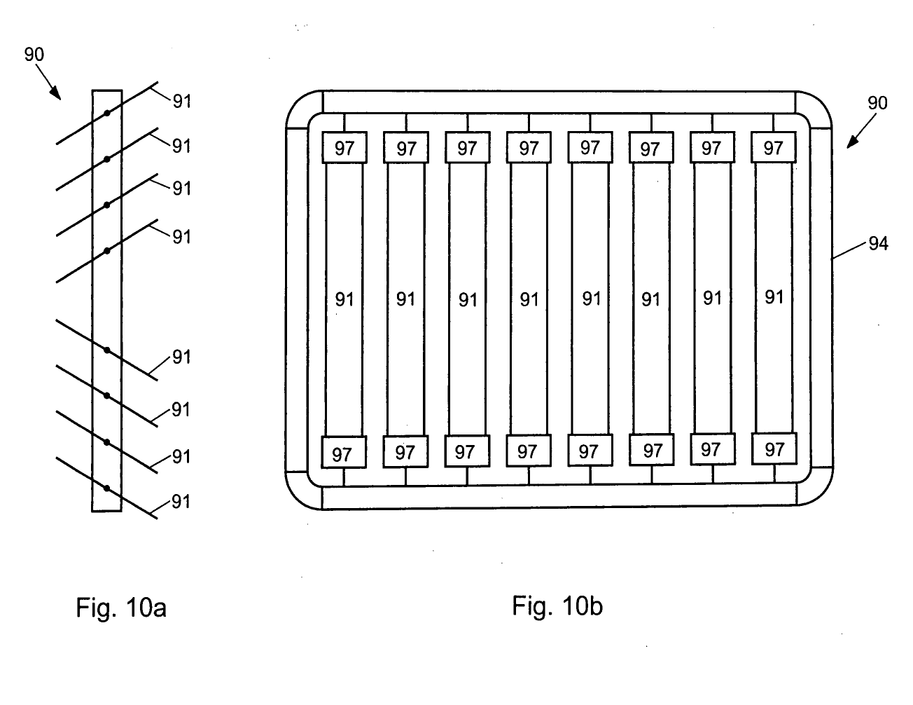

FIGS. 10a and 10b are schematic block diagrams of an embodiment of a guide mirror of the photovoltaic arrangement according to the invention for producing electric current from light;

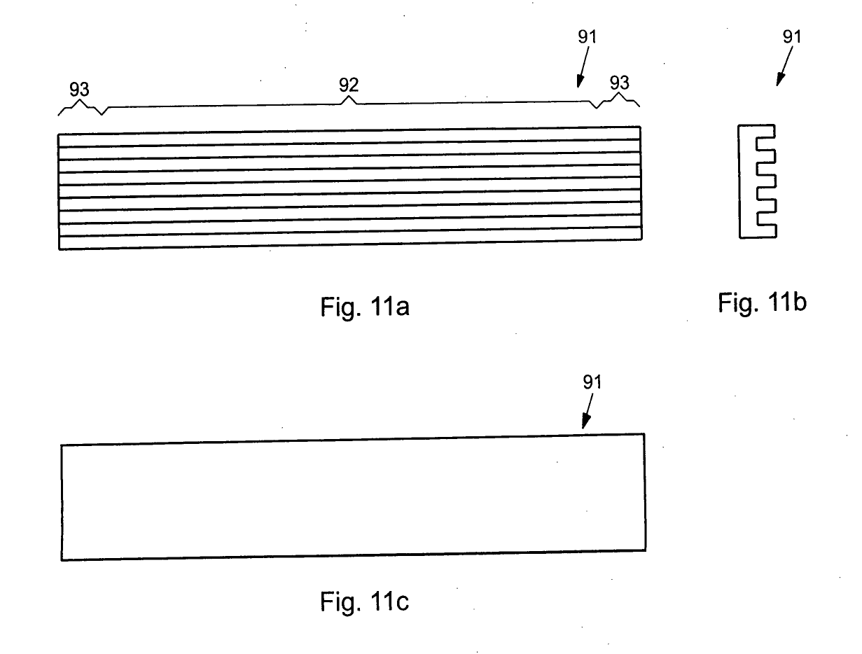

FIGS. 11a to 11c are schematic sectional views of an embodiment of a lamella of the guide mirror according to FIGS. 10a and 10b; and

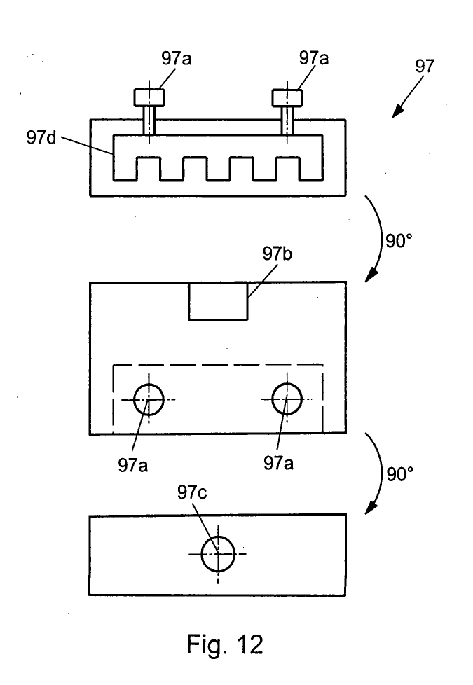

FIG. 12 shows schematic sectional views of an embodiment of a linking means for linking the lamellae to a frame of the guide mirror according to FIGS. 10a and 10b.

In all figures, like or functionally equivalent means and devices are provided with like reference numerals unless otherwise specified.

FIG. 1 is a schematic block diagram of a first embodiment of a photovoltaic arrangement 10 according to the invention for producing electric current from light.

The photovoltaic arrangement 10 or the system 10 has a photovoltaic installation 20 with a predetermined area. The photovoltaic installation 20 comprises a plurality of photovoltaic modules 31-39. Without any restriction to generality, FIG. 1 shows nine photovoltaic modules 31-39. Naturally, a photovoltaic installation 20 may have a greater number of photovoltaic modules 31-39, for example several hundred or even several thousand.

The photovoltaic arrangement 10 further comprises a number N of reflectors 41-44. Without any restriction to generality, FIG. 1 shows four reflectors 41-44 (N=4).

Each reflector 41-44 has an area which is greater than the area of the photovoltaic installation 20.

Each reflector 41-44 is further set up to guide or reflect at least part of the light incident on the respective reflector 41-44 onto the photovoltaic installation 20.

The area of each reflector 41-44 is greater than the determined area of the photovoltaic installation 20 by at least a factor F. The factor F is for example between 2 and 10, preferably between 3 and 8, particularly preferably between 4 and 6. The number N of reflectors 41-44 are in particular arranged in a trapezium arrangement around the photovoltaic installation 20. The trapezoid photovoltaic arrangement is formed for example as an isosceles trapezium. Thus, in this case, the known effect of a spotlight, for example an office light, is reversed.

Each large-area reflector 41-44 is formed for example as a canvas made from a plastics material. Alternatively, each large-area reflector 41-44 may be formed from a material with a reflective surface.

FIG. 2 is a schematic block diagram of a first embodiment of a reflector 41 of the photovoltaic arrangement 10 of FIG. 1 according to the invention. Each reflector 41 is for example formed as a canvas 41 and has a plurality of slits 50. The slits 50 are adapted to allow water to flow off and wind to pass through. The slits 50 thus protect the canvas 41 from damage caused by wind or rain.

FIG. 3 is a schematic block diagram of a second embodiment of a reflector 41 of the photovoltaic arrangement 10 according to the invention for producing electric current from light. In this case, the photovoltaic arrangement 10 comprises the reflector 41 according to FIG. 2 with the slits 50. The reflector 41, which is formed for example as a canvas, is fastened in a fastening frame 45. A guide means 62 is arranged on the fastening frame 45. The guide means 62 is set up to guide the respective canvas 41 for the optimum incidence of light. For example, the guide means 62 comprises an internal hexagon for engaging a polygon of a rod.

A height adjustment means 61 is also provided. The height adjustment means 61 and the guide means 62 form a fastening means 60 for fastening the respective canvas 41 to the ground 70 or to another fixed means.

The height adjustment means 61 is set up to adjust the height of the respective canvas 41 relative to the ground 70. Further, the height adjustment means 61 can be set up to arrange the respective canvas 41 at a predetermined angle and/or with a predetermined curvature.

In particular, the fastening means 60 comprises supports, in particular metal supports, for anchoring the respective canvas 41 in the ground.

FIGS. 4a and 4b are schematic block diagrams of a third embodiment of a reflector 41 of the photovoltaic arrangement 10 according to the invention for producing electric current from light. According to FIGS. 4a and 4b, the reflector 41 has a base 41a and angled faces 41a-41d arranged on the sides of the base 41a. In this case, the angled surfaces 41a-41d can be adjusted relative to the base 41a, in particular in terms of a respective adjustable angle.

FIGS. 5a and 5b are further schematic block diagrams of a fourth embodiment of a reflector 41 of the photovoltaic arrangement 10 according to the invention for producing electric current from light.

According to FIGS. 5a and 5b, the reflector 41 has a base 41a and a plurality of rotating faces 41f-41i arranged rotatably on the sides of the base 41a. Preferably, a respective rotating face 41f-41i is arranged on each side of the base 41a. The rotating faces 41f-41i can be arranged at an adjustable angle of rotation relative to the base 41a. This adjustment is preferably performed manually.

The embodiments of the reflector 41 according to FIGS. 4a, 4b, 5a and 5b all have the advantage that the reflectors 41 are particularly suitable for installations mounted on the ground 70 and for installations of sufficiently large roof area.

FIG. 6 is a schematic block diagram of a second embodiment of a photovoltaic arrangement 10 according to the invention for producing electric current from light. The second embodiment according to FIG. 6 comprises the first embodiment according to FIG. 1. The photovoltaic arrangement 10 according to FIG. 6 further comprises two reflectors 41, 44 which are constructed in accordance with the embodiment of FIG. 3. Furthermore, the reflectors 42, 43 are constructed as fixed reflectors, which are for example arranged on a roof of a house or other building.

The photovoltaic arrangement 10 according to FIG. 6 further comprises at least one light sensor means 21. The light sensor means 21 is arranged on or in the photovoltaic installation 10. Without any restriction to generality, the light sensor means 21 according to FIG. 6 is arranged on the photovoltaic installation 20. The light sensor means 21 generates a detection signal D in dependence on the light incident on the photovoltaic installation 20, in particular in dependence on the amount of light incident on the photovoltaic installation 20.

The photovoltaic arrangement 10 according to FIG. 6 further comprises a control means 80. The control means 80 is set up at least so as to control the guide means 62 and/or the height adjustment means 61 as a function of the detection signal D of the at least one light sensor means 21.

FIG. 7 is a schematic block diagram of a third embodiment of a photovoltaic arrangement 10 according to the invention for producing electric current from light. The photovoltaic arrangement 10 of FIG. 7 comprises a number N of reflectors 41-43 which are adapted to reflect at least part of the light incident on the number N of reflectors 41-43 onto a number M of guide mirrors 90. Without any restriction to the generality, FIG. 7 shows three reflectors (N=3).

The photovoltaic arrangement 10 further comprises the number M of guide mirrors 90. The M guide mirrors 90 are arranged in such a way as to guide the light reflected by the number N of reflectors 41 to 43 onto the photovoltaic installation 20. Without any restriction to generality, a single guide mirror 90 is provided in FIG. 7 (M=1).

Preferably, the number M of guide mirrors 90 is between 1 and 6, preferably between 1 and 3, particularly preferably 2. However, the number N of reflectors is preferably between 2 and 16, particularly preferably between 4 and 12 or particularly preferably between 4 and 6.

The photovoltaic installation 20 has a determined first area, the end reflectors 41-43 each having a determined second area and the M guide mirrors 90 each having a determined third area. The second area is greater than the first area and greater than the third area.

FIG. 8 is the schematic block diagram of the third embodiment of the photovoltaic arrangement 10 of FIG. 7 according to the invention, showing an example of the incidence of light L. FIG. 8 thus shows that each reflector 41-43 (the reflector 41 according to the embodiment in FIG. 8) is adapted to reflect a first part of the incident light L onto at least one of the guide mirrors 90 and a second part of the incident light L directly onto the photovoltaic installation 20 in a focused form.

FIG. 9 is a schematic block diagram of a fourth embodiment of a photovoltaic arrangement 10 according to the invention for producing electric current from light. The embodiment of FIG. 9 is based on the embodiment of FIG. 7 and comprises the features of the embodiment of FIG. 7, which in order to avoid repetition will not be expressly discussed again here. The embodiment of FIG. 9 further shows that a fastening device 95 is provided for reversibly fastening the guide mirror 90 to the ground 70. The fastening device 95 is in particular set up in such a way that the frame of the respective guide mirror 90 is mounted rotatably.

Further, the fastening device 95 preferably comprises a height adjustment device (not shown) for adjusting the height of the respective guide mirror 90 relative to the ground 70. Furthermore, the fastening device 95 preferably has a guide device (not shown) for adjusting the inclination and/or the angle of rotation of the respective guide mirror 90, which means is set up to guide the respective guide mirror 90 for the optimum incidence of light.

Furthermore, preferably at least one light sensor device 21 is arranged or on in the photovoltaic installation 20 and provides the detection signal D as a function of the light incident on the photovoltaic installation 20. Preferably, this detection signal D is used by a control device to control the guide device and/or the height adjustment device as a function of the detection signal. In particular, the control device may be part of the control means 80.

FIGS. 10a and 10b are schematic block diagrams of an embodiment of a guide mirror 90 of the photovoltaic arrangement 10 according to the invention for producing electric current from light. The respective guide mirror 90 has a plurality of lamellae 91, arranged parallel to one another, with reflective surfaces 92 (see FIG. 11). The lamellae 91 are mounted rotatably in a frame 94. The frame 94 is preferably produced from bonded plastics material tubes and has a weight of less than 10 kg.

The rotatably mounted lamellae 91 are preferably aligned so as to form a predetermined mirror shape, in particular a concave mirror. To control the formation of the predetermined mirror shape, a control device is preferably provided to control the alignment of the rotatably mounted lamellae 91. The control device is, as mentioned above, in particular part of the control means 80 and performs the control function thereof as a function of the detection signal D. To connect the respective lamellae 91 to the frame 94, two coupling means 97 are provided in each case. FIG. 10a illustrates the possibility of forming a concave mirror with the lamellae 91.

FIGS. 11a to 11c are schematic sectional views of an embodiment of a lamella 91 of the guide mirror 90 of FIGS. 10a and 10b. FIG. 11a shows the front, FIG. 11b shows the cross-section and FIG. 11c shows the back of the lamella 91. According to FIG. 11a, the majority of the surface of the lamella 91 is formed as a reflective surface 92. Only the edge regions 93 are formed as a non-reflective surface 93. The edge regions 93 are used for coupling to the coupling means 97.

FIG. 11b shows, in detail, a cross-sectional view of the lamella 91. According to FIG. 11b, the lamella 91 has a ribbed construction to increase the stability of the lamella 91.

Furthermore, FIG. 12 shows schematic sectional views of an embodiment of a coupling means 97 for connecting the lamella 91 to the frame 94 of the guide mirror 90 according to FIGS. 10a and 10b. The coupling means 97 has a holding means 97d for holding the respective lamella 91. The holding means 97d is formed as a negative of the lamella 91 as regards the rib construction. The coupling means 97 further comprises an engagement means 97b for manually rotating the coupling means 97. In particular, the engagement means 97b has an internal hexagon.

Furthermore, the coupling means 97 has a threaded sleeve 97c for a setscrew for fastening the coupling means 97.

Due to this photovoltaic arrangement with the coupling means 97, the lamella 91 can distort so much in the wind that it slips out of the coupling means 97 and gives way to the wind. This prevents damage to the lamella 91.

Although the present invention has been described in the above by way of preferred embodiments, it is not limited to these but can be modified in numerous ways.

List of reference numerals

| | |
|---|---|
| 10 | photovoltaic arrangement |
| 20 | photovoltaic installation |
| 21 | light sensor device |
| 31-39 | photovoltaic module |
| 41-44 | reflector |
| 41a | base |
| 41b-41e | angled face |
| 41f-41i | rotating face |
| 45 | fastening frame |
| 50 | slit |
| 60 | fastening means |
| 61 | height adjustment means |
| 62 | guide means |
| 63, 64 | support |
| 70 | ground |
| 80 | control means |
| 90 | guide mirror |
| 91 | lamella |
| 92 | reflective surface |
| 93 | non-reflective surface |
| 94 | frame |
| 95 | fastening device |
| 97 | coupling means |
| 97a | screw |
| 97b | engagement means |
| 97c | threaded sleeve |
| 97d | holding means |
| 100 | roof |
| D | detection signal |
| S | control signal |

1. Photovoltaic arrangement (10) for producing electric current from light, comprising:
a) a photovoltaic installation (20) with a predetermined area and having a plurality of photovoltaic modules (31-39); and
b) a number N of reflectors (41-44), each reflector (41-44) having a area which is greater than the area of the photovoltaic installation (20) and being arranged to reflect at least part of any light incident on the reflector (41-44) onto the photovoltaic installation (20).

2. Photovoltaic arrangement according to claim 1, characterised in that the area of the respective reflector (41-44) is greater than the determined area of the photovoltaic installation (20) at least by a factor F, the factor F preferably being between 1 and 6, particularly preferably between 1 and 3.

3. Photovoltaic arrangement according to any one of the preceding claims, characterised in that the number N of reflectors (41-44) is arranged in a trapezium arrangement around the photovoltaic installation (20); or in that the respective large-area reflector (41-44) comprises a canvas made of a plastics material or a material with a reflective surface (42).

4. Photovoltaic arrangement according to claim 3, characterised in that the respective canvas (41) comprises a plurality of slits (50), which are arranged to allow water to flow off and wind to pass through; or in that a respective fastening means (60) is provided for reversibly fastening the respective canvas (41) to the ground (70) or to a fixed means.

5. Photovoltaic arrangement according to claim 4, characterised in that the fastening means (60) comprises a height adjustment means (61) for adjusting the height of the respective canvas (41) relative to the ground (70); the height adjustment means (61) preferably being set up to arrange the respective canvas (41) at a predetermined angle and/or with a predetermined curvature.

6. Photovoltaic arrangement according to either claim 4 or claim 5, characterised in that the fastening means (60) comprises a guide means (62) which is arranged to guide the respective canvas (41) for the optimum incidence of light.

7. Photovoltaic arrangement according to either claim 5 or claim 6, characterised in that at least one light sensor means (21) is arranged on or in the photovoltaic installation (20) and provides a detection signal D in dependence on the light incident on the photovoltaic installation (20), in particular in dependence on the amount of light incident on the photovoltaic installation (20); and/or in that a control means (80) is provided for controlling the guide means (62) and/or the height adjustment means (61) in dependence on the detection signal D of the at least one light sensor means (21).

8. Photovoltaic arrangement (10) for producing electric current from light, comprising:
a) a photovoltaic installation (20) with a plurality of photovoltaic modules (31-39);
b) a number N of reflectors (41-43) which are adapted to reflect at least part of the light incident on the number N of reflectors (41-43) onto a number M of guide mirrors (90); and
c) the number M of guide mirrors (90), which are arranged in such a way as to guide the light reflected by the number N of reflectors (41-43) onto the photovoltaic installation (20).

9. Photovoltaic arrangement according to claim 8, characterised in that the number N of reflectors (41 to 43) is between 2 and 16, preferably between 4 and 12, particularly preferably between 4 and 6, and/or in that the number M of guide mirrors (90) is between 1 and 6, preferably between 1 and 3, particularly preferably 2.

10. Photovoltaic arrangement according to either claim 8 or claim 9, characterised in that the respective reflector (41-43) is adapted to reflect a first part of the incident light onto at least one of the guide mirrors (90) and a second part of the incident light directly onto the photovoltaic installation (20) in a focused form; and/or in that the photovoltaic installation (20) has a determined first area, the N reflectors (41-43) have a determined second area, and the M guide mirrors (90) have a determined third area, the second area being greater than the first area and greater than the third area; and/or in that the respective guide mirror (90) comprises a plurality of lamellae (91), arranged parallel to one another, with reflective surfaces (92), which lamellae are rotatably mounted in a frame (94).

11. Photovoltaic arrangement according to claim 10, characterised in that the rotatably mounted lamellae (91) are adapted to form a predetermined mirror shape, in particular a concave mirror, wherein a control device (80) preferably being provided for controlling the alignment of the rotatably mounted lamellae (91) and for controlling the construction of the predetermined mirror shape.

12. Photovoltaic arrangement according to either claim 10 or claim 11, characterised in that a respective fastening device (95) is provided for reversibly fastening each guide mirror (90) to the ground (70) or to a fixed means, on which the frame (4) of the respective guide mirror (90) is rotatably mounted, the fastening device (95) preferably comprising a height adjustment device for adjusting the height of the respective guide mirror (90) relative to the ground (70) and a guide device for adjusting the inclination and/or the angle of rotation of the respective guide mirror (90), wherein the height adjustment device is adapted to guide the respective guide mirror (90) for the optimum incidence of light; and/or in that the reflector (41-44) is formed as a sail (41) and the fastening means (95) comprises a break-off means which is adapted to tear in strong winds so as to prevent damage caused by the sail (41).

13. Photovoltaic arrangement according to claim 12, characterised in that at least one light sensor device (21) is arranged on or in the photovoltaic installation (20), and provides a detection signal (D) in dependence on the light incident on the photovoltaic installation (20), in particular in dependence on the amount of light incident on the photovoltaic installation (20), wherein a control device (80) preferably being provided for controlling the guide device and/or the height adjustment device in dependence on the detection signal (D) of the at least one light sensor device (21).

14. Photovoltaic arrangement according to any one of claims 10 to 13, characterised in that the lamellae (91) are produced from plastics material by an extrusion process, one side of each lamella (91) being coated with a reflective metallised film (92).

15. Photovoltaic arrangement (10) for producing electric current from light, comprising:
a) a photovoltaic installation (20) with a plurality of photovoltaic modules (31-39); and
b) a number M of guide mirrors (90) which are arranged in such a way as to guide light onto the photovoltaic installation (20), each guide mirror (90) comprising a plurality of lamellae (91), arranged parallel to one another, with reflective surfaces (92), which lamellae are mounted rotatably in a frame (94), the rotatably mounted lamellae (91) being arranged to form a particular mirror shape, in particular a concave mirror.
